(19) United States
(12) Patent Application Publication
(10) Pub. No.: US 2025/0306477 A1
(43) Pub. Date: Oct. 2, 2025

(54) SINGLE GRAB PUPIL LANDSCAPE VIA OUTSIDE THE OBJECTIVE LENS BROADBAND ILLUMINATION

(71) Applicant: KLA Corporation, Milpitas, CA (US)

(72) Inventors: Yaniv Weiss, Tel Aviv (IL); Yuval Lubashevsky, Haifa (IL); Andrew V. Hill, Sunriver, OR (US); Vladimir Levinski, Migdal Ha'emek (IL); Daria Negri, Nesher (IL)

(21) Appl. No.: 18/618,280

(22) Filed: Mar. 27, 2024

(51) Int. Cl. G03F 7/00; G01B 11/14; G06T 7/00

(52) U.S. Cl. CPC G03F 7/706845; G01B 11/14; G03F 7/70633; G03F 7/70666; G03F 7/706837; G03F 7/706847; G03F 7/706849; G03F 7/706851; G06T 7/0004; G06T 2207/30148

(57) ABSTRACT

An overlay metrology system may include a collection sub-system with an objective lens and detector located at a pupil plane. The system may include an illumination sub-system with illumination optics to direct one or more broadband illumination beams to an overlay target on a sample at incidence angles outside a numerical aperture of the objective lens, where the overlay target includes one or more cells having periodic features formed grating-over-grating structures. The system may further include a controller to receive pupil images of the cells from the detector, where a respective one of the one or more pupil images include first-order diffraction from at least one of the one or more broadband illumination beams, wherein spectra of the first-order diffraction is spectrally dispersed in the pupil plane. The controller may further generate an overlay measurement of the sample based on selected portions of the one or more pupil images.

### TECHNICAL FIELD

The present disclosure relates generally to overlay metrology and, more particularly, to scatterometry overlay metrology.

### BACKGROUND

Overlay metrology generally refers to measurements of the relative alignment of layers on a sample such as, but not limited to, semiconductor devices. An overlay measurement, or a measurement of overlay error, typically refers to a measurement of the misalignment of fabricated features on two or more sample layers. In a general sense, proper alignment of fabricated features on multiple sample layers is necessary for proper functioning of the device.

Demands to decrease feature size and increase feature density are resulting in correspondingly increased demand for accurate and efficient overlay metrology. Metrology systems typically generate metrology data associated with a sample by measuring or otherwise inspecting dedicated metrology targets distributed across the sample.

In typical metrology systems, the measurement is performed with monochromatic light. Finding the optimal wavelength requires many time-consuming, single wavelength measurements. The specific wavelength for the recipe is chosen such that it lies in a “green zone” (i.e., where the overlay slope is low and not sensitive to wavelength changes or focus changes) of the pupil landscape of the metrology target. The landscape itself may vary due to process related reasons, thus pushing the predetermined wavelength of the recipe out of the “green zone.”

Typical metrology systems further perform data collection and illumination using a common apparatus (e.g., through a common objective lens). However, this approach may limit the viable target pitches as well as amount of data that may be collected, particularly when using pupil-plane measurement techniques.

Therefore, it is desirable to provide systems and methods for curing the above deficiencies.

### SUMMARY

In embodiments, the techniques described herein relate to an overlay metrology system including a collection sub-system including an objective lens and detector located at a pupil plane; an illumination sub-system including one or more broadband illumination sources configured to generate one or more broadband illumination beams; and one or more illumination optics configured to direct the one or more broadband illumination beams to an overlay target on a sample at incidence angles outside a numerical aperture of the objective lens, where the overlay target in accordance with a metrology recipe includes one or more cells having periodic features formed grating-over-grating structures; and a controller communicatively coupled to the detector, the controller including one or more processors configured to execute program instructions causing the one or more processors to implement the metrology recipe by receiving one or more pupil images of the one or more cells from the detector in the pupil plane, where a respective one of the one or more pupil images include first-order diffraction from at least one of the one or more broadband illumination beams, where spectra of the first-order diffraction is spectrally dispersed in the pupil plane; and generating an overlay measurement of the sample based on selected portions of the one or more pupil images corresponding to selected wavelengths of the spectra of the first-order diffraction.

In embodiments, the techniques described herein relate to an overlay metrology system, where the one or more pupil images include a first pupil image of a first cell of the overlay target and a second pupil image of a second cell of the overlay target.

In embodiments, the techniques described herein relate to an overlay metrology system, where a respective one of the one or more pupil images is formed based on two mutually coherent broadband illumination beams of the one or more broadband illumination beams.

In embodiments, the techniques described herein relate to an overlay metrology system, where the two mutually coherent broadband illumination beams are oriented at opposing azimuth incidence angles.

In embodiments, the techniques described herein relate to an overlay metrology system, where the respective one of the one or more pupil images is formed based on a single lobe of the first-order diffraction from each of the two mutually coherent broadband illumination beams.

In embodiments, the techniques described herein relate to an overlay metrology system, where the overlay measurement is based on per-pixel overlay measurements associated with a plurality of wavelengths in the first-order diffraction.

In embodiments, the techniques described herein relate to an overlay metrology system, where generating the overlay measurement of the sample based on the selected portions of the one or more pupil images corresponding to the selected wavelengths of the spectra of the first-order diffraction further includes identifying one or more regions of the one or more pupil images associated with the selected wavelengths, where the one or more regions correspond to one or more regions of stability providing insensitivity of the overlay measurement to overlay process variations within a selected tolerance.

In embodiments, the techniques described herein relate to an overlay metrology system, where the one or more broadband illumination sources include a rotated quadrupole illumination source providing oblique illumination beams along two orthogonal directions in the pupil plane.

In embodiments, the techniques described herein relate to an overlay metrology system, where the one or more processors are further configured to store the overlay measurement in memory when implementing the metrology recipe; and adjust one or more process parameters based on the overlay measurement.

In embodiments, the techniques described herein relate to an overlay metrology system, where the detector includes a charge-coupled device or a complementary metal oxide semiconductor device.

In embodiments, the techniques described herein relate to an overlay metrology system, where the sample includes a substrate.

In embodiments, the techniques described herein relate to an overlay metrology system, where the sample includes a wafer.

In embodiments, the techniques described herein relate to an overlay metrology system including a controller communicatively coupled to a detector in a pupil plane of a collection sub-system, the controller including one or more processors configured to execute program instructions causing the one or more processors to implement a metrology recipe by receiving one or more pupil images of one or more cells of an overlay target on a sample from the detector, where the one or more pupil images are generated based on illumination of the overlay target with one or more broadband illumination beams at incidence angles outside a numerical aperture of an objective lens of the collection sub-system, where a respective one of the one or more pupil images include first-order diffraction from at least one of the one or more broadband illumination beams, where spectra of the first-order diffraction is spectrally dispersed in the pupil plane; and generating an overlay measurement of the sample based on selected portions of the one or more pupil images corresponding to selected wavelengths of the spectra of the first-order diffraction.

In embodiments, the techniques described herein relate to an overlay metrology system, where the one or more pupil images include a first pupil image of a first cell of the overlay target and a second pupil image of a second cell of the overlay target.

In embodiments, the techniques described herein relate to an overlay metrology system, where a respective one of the one or more pupil images is formed based on two mutually coherent broadband illumination beams of the one or more broadband illumination beams.

In embodiments, the techniques described herein relate to an overlay metrology system, where the two mutually coherent broadband illumination beams are oriented at opposing azimuth incidence angles.

In embodiments, the techniques described herein relate to an overlay metrology system, where the respective one of the one or more pupil images is formed based on a single lobe of the first-order diffraction from each of the two mutually coherent broadband illumination beams.

In embodiments, the techniques described herein relate to an overlay metrology system, where the overlay measurement is based on with per-pixel overlay measurements associated with a plurality of wavelengths in the first-order diffraction.

In embodiments, the techniques described herein relate to an overlay metrology system, where generating the overlay measurement of the sample based on the selected portions of the one or more pupil images corresponding to the selected wavelengths of the spectra of the first-order diffraction further includes identifying one or more regions of the one or more pupil images associated with the selected wavelengths, where the one or more regions correspond to one or more regions of stability providing insensitivity of the overlay measurement to overlay process variations within a selected tolerance.

In embodiments, the techniques described herein relate to an overlay metrology system, where the one or more broadband illumination beams are in a rotated quadrupole distribution.

In embodiments, the techniques described herein relate to an overlay metrology system, where the detector includes a charge-coupled device or a complementary metal oxide semiconductor detector.

In embodiments, the techniques described herein relate to an overlay metrology system, where the one or more processors are further configured to store the overlay measurement in memory when implementing the metrology recipe; and adjust one or more process parameters based on the overlay measurement.

In embodiments, the techniques described herein relate to an overlay metrology system, where the sample includes a substrate.

In embodiments, the techniques described herein relate to an overlay metrology system, where the sample includes a wafer.

In embodiments, the techniques described herein relate to a method including generating one or more broadband illumination beams with one or more broadband illumination sources; directing the one or more broadband illumination beams to an overlay target on a sample at incidence angles outside a numerical aperture of an objective lens of a collection sub-system when implementing a metrology recipe, where the overlay target in accordance with the metrology recipe includes one or more cells having periodic features formed grating-over-grating structures; generating one or more pupil images of the one or more cells from a detector in a pupil plane of the collection sub-system, where a respective one of the one or more pupil images include first-order diffraction from at least one of the one or more broadband illumination beams, where spectra of the first-order diffraction is spectrally dispersed in the pupil plane; and generating an overlay measurement of the sample based on selected portions of the one or more pupil images corresponding to selected wavelengths of the spectra of the first-order diffraction.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A is a conceptual view of an overlay metrology system for performing scatterometry overlay metrology on an overlay target on a sample with one or more broadband illumination beams in an outside the lens (OTL) configuration, in accordance with one or more embodiments of the present disclosure.

FIG. 1B is a conceptual schematic depicting the optical sub-system of the overlay metrology system, in accordance with one or more embodiments of the present disclosure.

FIG. 2 is a side view of a grating-over-grating structure in an overlay target suitable for scatterometry overlay measurements, in accordance with one or more embodiments of the present disclosure.

FIG. 3 is a three-dimensional perspective top view of a sample depicting diffraction of two broadband illumination beams in a rotated dipole configuration, in accordance with one or more embodiments of the present disclosure.

FIG. 4 is a simplified schematic depicting the collection of first-order diffraction from an illumination beam in an OTL configuration, in accordance with one or more embodiments of the present disclosure.

FIG. 5 depicts a top view of a pupil plane depicting simultaneous collection of spectrally-dispersed first-order diffraction from two azimuthally-opposed illumination beams in a rotated dipole configuration, in accordance with one or more embodiments of the present disclosure.

FIG. 6 is a plot of a full pupil landscape generated by pupil images of the type depicted in FIG. 5, in accordance with one or more embodiments of the present disclosure.

FIG. 7 depicts a plot of K and G datapoints generated based on bins generated parallel to a wavelength dispersion direction in pupil images, in accordance with one or more embodiments of the present disclosure.

FIG. 8 depicts a plot of K and G datapoints generated based on bins generated perpendicular to a wavelength dispersion direction in pupil images, in accordance with one or more embodiments of the present disclosure.

FIG. 9 is a flowchart depicting a method for taking overlay measurements using a broadband illumination source, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for scatterometry overlay metrology based on broadband illumination in an outside-the-lens (OTL) configuration, where periodic features on the overlay metrology target act as a diffraction grating to generate spectrally-dispersed diffraction orders that are captured by a pupil plane detector. For example, an overlay metrology system may direct one or more broadband illumination beams to an overlay target on a sample (or a cell thereof) having overlapping periodic structures, which are referred to herein as grating-over-grating structures. The overlay metrology system may then include an objective lens to capture selected diffraction orders from the overlapping periodic structures and a detector at a pupil plane to generate pupil images that may include spectrally-dispersed diffraction orders from the overlapping periodic structures. Notably, the illumination beams may be directed to the sample at angles outside objective lens. As a result, the pupil images may be free of zero-order diffraction (e.g., specular reflection) of the illumination beams.

It is recognized herein that many scatterometry overlay metrology techniques generally determine overlay by illuminating an overlay target having grating structures in two layers (e.g., grating-over-grating structures), where an overlay measurement is based on asymmetries between positive and negative diffraction orders. For example, various scatterometry techniques are described in U.S. Patent Publication No. 2021/0364279 published on Mar. 11, 2021; U.S. Pat. No. 10,824,079 issued on Nov. 3, 2020; U.S. Pat. No. 10,197,389 issued on Feb. 9, 2019; and Adel, et al., “Diffraction order control in overlay metrology: a review of the roadmap options,” Proc. SPIE. 6922, Metrology, Inspection, and Process Control for Microlithography XXII, 692202. (2008); all of which are incorporated herein by reference in their entireties.

Existing scatterometry overlay measurements are commonly performed using monochromatic light. Finding the optimal wavelength when using monochromatic light requires multiple, time-consuming, single wavelength measurements (i.e., the pupil landscape). In such systems, the specific wavelength for the recipe is chosen such that it lies in a “green zone” of the pupil landscape of the target. However, the landscape itself may vary due to process related reasons, thus pushing the recipe predetermined wavelength out of the green zone. For purposes of the present disclosure, the term “green zone”, “region of stability”, and variations thereof may be defined as an area in which a measurement is relatively stable with respect to deviations of process parameters. For example, the “green zone” may be an area where an overlay measurement is relatively insensitive to process variations such as, but not limited to, wavelength changes or focus changes. Put another way, the “green zone” may correspond to a set of process parameters for which an overlay slope (e.g., a rate of change of overlay in response to deviations of the process parameters) is relatively low.

However, it is contemplated herein that scatterometry overlay metrology utilizing broadband illumination may provide numerous benefits over traditional monochromatic (e.g., single band) illumination such as, but not limited to, alleviating issues with changing green zones (e.g., the set of wavelengths for which an overlay measurement may be stable) by using a variety of wavelengths to obtain an overlay measurement. Additionally, scatterometry overlay metrology utilizing broadband illumination may allow for more robust measurements based on the additional data associated with diffraction orders generated at multiple-wavelengths.

Scatterometry overlay metrology utilizing broadband illumination beams directed to a sample through the same objective lens used to collect the spectrally-dispersed diffraction orders (e.g., a through-the-lens (TTL) configuration) is generally described in U.S. patent application Ser. No. 18/370,136 filed on Sep. 19, 2023 titled SINGLE GRAB PUPIL LANDSCAPE VIA BROADBAND ILLUMINATION, which is incorporated herein by reference.

It is contemplated herein that scatterometry overlay metrology utilizing broadband illumination beams directed to a sample through the same objective lens used to collect the spectrally-dispersed diffraction orders may have potential disadvantages, which may be cured by the systems and methods disclosed herein that utilize an OTL configuration. For example, a TTL configuration may limit the minimum pitch of grating-over-grating structures in an overlay target. As an illustration, pitches lower than approximately 400 nm may be inaccessible with a TTL configuration due to illumination and collection numerical aperture constraints, particularly when using quadrupole illumination beams. As another example, the TTL configuration results in capture of zero-order diffraction (e.g., specular reflection) of the illumination beams, which both increases a risk of detector blooming (e.g., detector saturation) that may negatively impact a measurement and decreases the available space in the pupil available for the spectrally-dispersed diffraction orders of interest. In contrast, an OTL configuration as disclosed herein may allow smaller pitches of the grating-over-grating structures in an overlay target and may maximize the pupil area available to capture the spectrally-dispersed diffraction. Further, zero-order diffraction is not captured by the system such that blooming is mitigated.

Additionally, OTL illumination for metrology is generally described in U.S. Pat. No. 11,359,916 issued on Jun. 14, 2022, titled DARKFIELD IMAGING OF GRATING TARGET STRUCTURES FOR OVERLAY MEASUREMENT, which is incorporated herein by reference in its entirety. Notably, whereas U.S. Pat. No. 11,359,916 focuses on dark-field imaging (e.g., configurations in which a detector is located at a field plane), the present disclosure focuses on pupil-based detection in which a detector is located in a pupil plane. As a result, both the systems and methods disclosed herein are distinguished from those in U.S. Pat. No. 11,359,916.

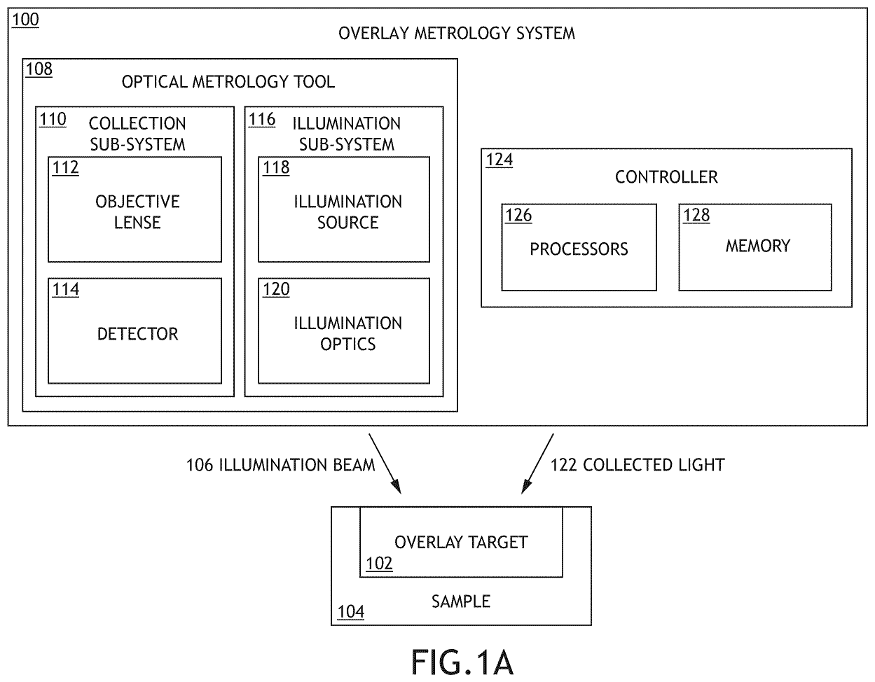

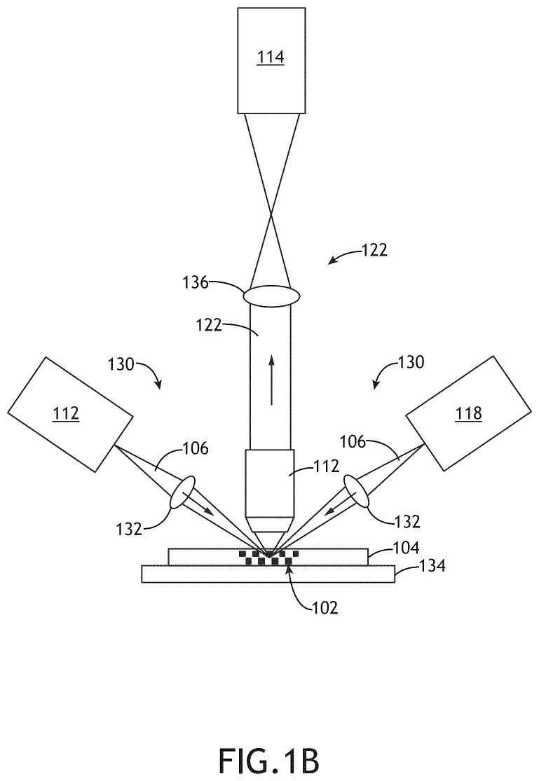

Referring now to FIGS. 1A-6, systems and methods for scatterometry overlay metrology are described in greater detail, in accordance with one or more embodiments of the present disclosure.

FIG. 1A is a conceptual view of an overlay metrology system 100 for performing scatterometry overlay metrology on an overlay target 102 on a sample 104 with one or more broadband illumination beams 106 in an OTL configuration, in accordance with one or more embodiments of the present disclosure.

In embodiments, the overlay metrology system 100 includes an optical sub-system 108 to acquire measurement data (e.g., overlay signals) associated with an overlay target 102 (or a portion thereof), where the overlay target 102 includes one or more grating-over-grating structures. For example, the optical sub-system 108 may include a collection sub-system 110 including an objective lens 112 and a detector 114 located at a pupil plane (e.g., a back focal plane of the objective lens 112 or a conjugate plane thereof). The optical sub-system 108 may then include an illumination sub-system 116 including one or more illumination sources 118 to generate the one or more broadband illumination beams 106, and one or more illumination optics 120 to direct the one or more illumination beams 106 to the overlay target 102 along oblique incidence angles that lie outside the objective lens 112 (e.g., in an OTL configuration).

In this configuration, grating-over-grating structures in the overlay target 102 may diffract the one or more broadband illumination beams 106 into spatially-dispersed diffraction orders. The objective lens 112 may then capture light emanating from the overlay target 102 in response to the one or more illumination beams 106, which is referred to herein as collected light 122. In embodiments, the objective lens 112 may be configured in accordance with a metrology recipe to capture one or more selected spatially-dispersed diffraction orders (e.g., as collected light 122). As an illustration, the objective lens 112 may collect spatially-dispersed first-order diffraction from the overlay target 102. The detector 114 may then generate one or more pupil images including at least some of these spatially-dispersed diffraction orders.

In embodiments, the overlay metrology system 100 includes a controller 124. The controller 124 may include one or more processors 126 and/or a memory 128 (e.g., memory medium). The one or more processors 126 of the controller 124 may execute any of the various process steps described throughout the present disclosure. Further, the controller 124 may be communicatively coupled to the optical sub-system 108 or any component therein.

The one or more processors 126 of a controller 124 may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 126 may include any device configured to execute algorithms and/or instructions (e.g., program instructions stored in memory). In embodiments, the one or more processors 126 may be embodied as a desktop computer, mainframe computer system, workstation, image computer, parallel processor, networked computer, or any other computer system configured to execute a program configured to operate or operate in conjunction with the overlay metrology system 100, as described throughout the present disclosure.

Moreover, different subsystems of the overlay metrology system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller 124 or, alternatively, multiple controllers. Additionally, the controller 124 may include one or more controllers housed in a common housing or within multiple housings. In this way, any controller or combination of controllers may be separately packaged as a module suitable for integration into the overlay metrology system 100.

The memory 128 may include any storage medium known in the art suitable for storing program instructions executable by the associated one or more processors 126. For example, the memory 128 may include a non-transitory memory medium. By way of another example, the memory 128 may include, but is not limited to, a read-only memory (ROM), a random-access memory (RAM), a magnetic or optical memory device (e.g., disk), a magnetic tape, a solid-state drive and the like. It is further noted that memory 128 may be housed in a common controller housing with the one or more processors 126. In embodiments, the memory 128 may be located remotely with respect to the physical location of the one or more processors 126 and controller 124. For instance, the one or more processors 126 of controller 124 may access a remote memory (e.g., server), accessible through a network (e.g., internet, intranet, and the like).

For the purposes of the present disclosure, the term “overlay” is generally used to describe relative positions of features on an overlay target 102 fabricated by two or more lithographic patterning steps, where the term “overlay error” describes a deviation of the features from a nominal arrangement. In this context, an overlay measurement may be expressed as either a measurement of the relative positions of the features or as an overlay error associated with these relative positions. For example, a multi-layered device may include features patterned on multiple sample layers using different lithography steps for each layer, where the alignment of features between layers must typically be tightly controlled to ensure proper performance of the resulting device. Accordingly, an overlay measurement may characterize the relative positions of features on two or more of the sample layers. It is to be understood that examples and illustrations throughout the present disclosure relating to a particular application of overlay metrology are provided for illustrative purposes only and should not be interpreted as limiting the disclosure.

For the purposes of the present disclosure, the term “scatterometry metrology” is used to broadly encompass the terms “scatterometry-based metrology” and “diffraction-based metrology” in which a sample having periodic features on one or more sample layers is illuminated with an illumination beam having a limited angular extent and one or more distinct diffraction orders are collected for the measurement.

As used throughout the present disclosure, the term sample 104 generally refers to a substrate formed of a semiconductor or non-semiconductor material (e.g., a wafer, or the like). For example, a semiconductor or non-semiconductor material may include, but is not limited to, monocrystalline silicon, gallium arsenide, and indium phosphide. A sample may include one or more layers. For example, such layers may include, but are not limited to, a resist, a dielectric material, a conductive material, and a semiconductive material. Many different types of such layers are known in the art, and the term sample 104 as used herein is intended to encompass a material on which all types of such layers may be formed. One or more layers formed on a sample 104 may generally be patterned or unpatterned. For example, a sample 104 may include a plurality of dies, each having repeatable patterned features. Formation and processing of such layers of material may ultimately result in completed devices. Many different types of devices may be formed on a sample 104, and the term sample 104 as used herein is intended to encompass a sample on which any type of device known in the art is being fabricated. Further, for the purposes of the present disclosure, the term sample 104 and wafer should be interpreted as interchangeable. In addition, for the purposes of the present disclosure, the terms patterning device, mask and reticle should be interpreted as interchangeable.

Some embodiments of the present disclosure are directed to providing recipes for configuring an optical sub-system 108. For example, the optical sub-system 108 may be configurable according to a metrology recipe including a set of parameters for controlling various aspects of an overlay measurement such as, but not limited to, the illumination of a sample 104, the collection of light from the sample 104, or the position of the sample 104 during a measurement. In this way, the optical sub-system 108 may be configured to provide a selected type of measurement for one or more overlay target designs of interest. For example, a metrology recipe may include illumination parameters such as, but not limited to, a number of illumination beams 106, wavelengths or spectra more generally of one or more illumination beams 106, an illumination pupil distribution (e.g., a distribution of illumination angles and associated intensities of illumination at those angles), a polarization of incident illumination beams 106, or a spatial distribution of one or more illumination beams 106 on a sample 104. By way of another example, a metrology recipe may include collection parameters such as, but not limited to, a collection pupil distribution (e.g., a desired distribution of angular light from the sample to be used for a measurement and associated filtered intensities at those angles), collection field stop settings to select portions of the sample 104 interrogated for a measurement, polarization of collected light 122, wavelength filters, a position of a detector 114 or parameters for controlling a detector 114. By way of a further example, a metrology recipe may include various parameters associated with the sample position during a measurement such as, but not limited to, a sample height, a sample orientation, whether a sample 104 is static during a measurement, or whether a sample is in motion during a measurement (along with associated parameters describing the speed, scan pattern, or the like).

Some embodiments of the present disclosure are directed to providing overlay data to one or more process tools. Overlay data from an overlay metrology system 100 may generally include any output of the overlay metrology system 100 having sufficient information to determine overlay (or overlay errors) associated with various lithography steps. For example, overlay data may include, but is not required to include, overlay values, overlay error values, one or more pupil images, one or more detector readings, or the like. This overlay data may then be used for various purposes including, but not limited to, diagnostic information of the lithography tools or for the generation of process-control correctables. For instance, overlay data for samples in a lot may be used to generate feedback correctables for controlling the lithographic exposure of subsequent samples in the same lot. In another instance, overlay data for samples in a lot may be used to generate feed-forward correctables for controlling lithographic exposures for the same or similar samples in subsequent lithography steps to account for any deviations in the current exposure.

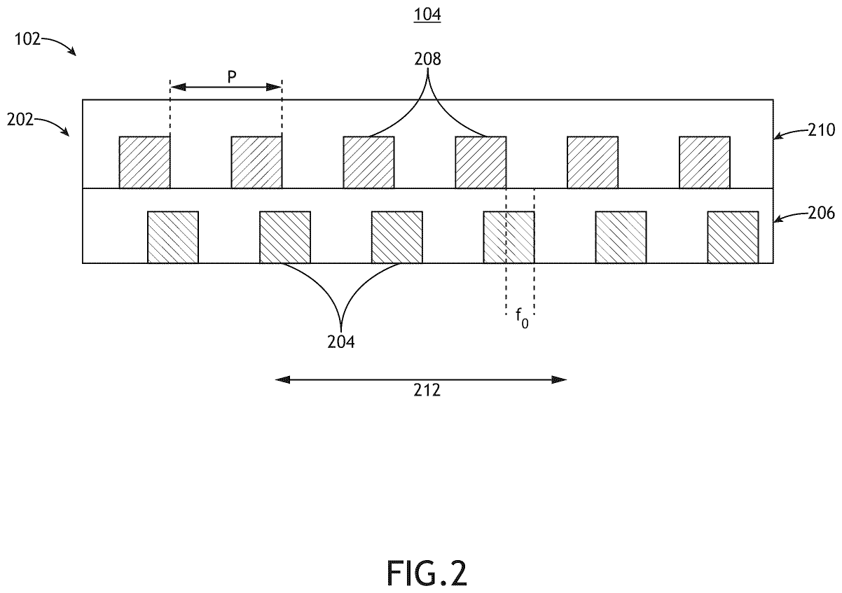

FIG. 2 is a side view of a grating-over-grating structure 202 in an overlay target 102 suitable for scatterometry overlay measurements, in accordance with one or more embodiments of the present disclosure.

In embodiments, the overlay target 102 includes one or more grating-over-grating structure 202. For example, a grating-over-grating structure 202 may include a first periodic feature 204 on a first layer 206 of the sample 104 and a second periodic feature 208 on a second layer 210 of the sample 104, where the first periodic feature 204 overlaps with the second periodic feature 208. Further, the first periodic feature 204 and the second periodic feature 208 have a common pitch P as well as a common direction of periodicity (e.g., grating direction), which may also correspond to a measurement direction 212.

The first periodic feature 204 and the second periodic feature 208 may have any intended arrangement along the measurement direction 212. As an illustration, FIG. 2 depicts a configuration in which the grating-over-grating structure 202 includes an intended offset f₀ between the first periodic feature 204 and the second periodic feature 208 along the measurement direction 212.

An overlay target 102 may further include any number of grating-over-grating structures 202 suitable for providing an overlay measurement based on any selected metrology recipe. It is contemplated herein that various scatterometry overlay techniques have been developed that utilize different numbers and configurations of grating-over-grating structures 202. Scatterometry techniques are generally described in Adel, Mike, et al. “Diffraction order control in overlay metrology: a review of the roadmap options.” Metrology, Inspection, and Process Control for Microlithography XXII 6922 (2008): 23-41; which is incorporated herein by reference in its entirety.

In embodiments, an overlay target 102 includes multiple cells, where each cell includes a grating-over-grating structure 202 with a unique combination of measurement direction 212 and intended offset. For example, an overlay target 102 suitable for overlay measurements based on the first-order diffraction (e.g., first-order SCOL) may have two cells per measurement direction 212, where the two cells per measurement direction 212 have grating-over-grating structures 202 with different intended offsets (e.g., ±f₀) along the measurement direction 212. In such a configuration, separate pupil images may be generated for each cell (e.g., each grating-over-grating structure 202) and an overlay measurement may be generated in accordance with a metrology recipe based on these separate pupil images.

It is to be understood, however, that the overlay target 102 in FIG. 2 and the associated description are provided solely for illustrative purposes and should not be interpreted as limiting. Rather, the overlay target 102 may include any suitable grating-over-grating overlay target design. For example, the overlay target 102 may include any number of cells suitable for measurements along two directions. Further, the cells may be distributed in any pattern or arrangement.

Referring now to FIG. 1B, additional aspects of the optical sub-system 108 are described in greater detail. FIG. 1B is a conceptual schematic depicting the optical sub-system 108 of the overlay metrology system 100, in accordance with one or more embodiments of the present disclosure.

In embodiments, the optical sub-system 108 includes at least one illumination source 118 configured to generate the one or more illumination beams 106.

A broadband illumination beam 106 may include any wavelengths or spectral content in any spectral band including, but not limited to, ultraviolet (UV) radiation, visible radiation, or infrared (IR) radiation. An illumination beam 106 may have any bandwidth suitable for generating at least one spectrally-dispersed diffraction order in a pupil plane of the collection sub-system 110. In some embodiments, a broadband illumination beam 106 has a bandwidth of 30 nm or greater.

The illumination sub-system 116 may include any number or type of illumination sources 118 suitable for providing one or more illumination beams 106. In embodiments, an illumination source 118 is a laser source such as, but is not limited to, a broadband laser source, a supercontinuum laser source, a white light laser source, or the like. In this regard, the illumination source 118 may provide an illumination beam 106 having high coherence (e.g., high spatial coherence and/or temporal coherence). In embodiments, the illumination source 118 includes a laser-sustained plasma (LSP) source. For example, the illumination source 118 may include, but is not limited to, a LSP lamp, a LSP bulb, or a LSP chamber suitable for containing one or more elements that, when excited by a laser source into a plasma state, may emit broadband illumination. In embodiments, the illumination source 118 includes a lamp source. For example, the illumination source 118 may include, but is not limited to, an arc lamp, a discharge lamp, an electrode-less lamp, or the like. In this regard, the illumination source 118 may provide an illumination beam 106 having low coherence (e.g., low spatial coherence and/or temporal coherence).

The illumination sub-system 116 may include any number of illumination sources 118 to generate the one or more illumination beams 106. As an example, each illumination beam 106 may be generated by a separate illumination source 118. As another example, two or more illumination beams 106 may be generated from a common illumination source 118. For instance, light from an illumination source 118 may be split (e.g., using beamsplitters, diffractive optics, or the like) into two or more illumination beams 106.

Further, in an application utilizing two or more illumination beams 106, the two or more illumination beams 106 may be arranged in any pattern. In some embodiments, two illumination beams 106 are arranged in a dipole pattern at opposing azimuth angles, where the azimuth angles may either be aligned with the measurement direction 212 or offset from the measurement direction 212 (e.g., in a rotated dipole configuration). In some embodiments, four illumination beams 106 are arranged in a quadrupole pattern formed as two dipoles, where the azimuth angles associated with each dipole may either be aligned with a measurement direction 212 or offset from the measurement direction 212 (e.g., in a rotated quadrupole configuration).

In embodiments, the optical sub-system 108 directs the illumination beam 106 to the sample 104 through one or more illumination channels 130. For example, each illumination beam 106 may be provided through a separate illumination channel 130.

Each illumination channel 130 may include one or more optical components suitable for modifying and/or conditioning the illumination beam 106 as well as directing the illumination beam 106 to the sample 104. For example, each illumination channel 130 may include, but is not required to include, one or more illumination lenses 132 (e.g., to control a spot size of the illumination beam 106 on the sample 104, to relay pupil and/or field planes, or the like), one or more polarizers to adjust the polarization of the illumination beam 106 in the channel, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In embodiments, the optical sub-system 108 includes a sample stage 134 to secure and position the sample 104. The sample stage 134 may include any number or type of actuators to position the sample stage 134 within any number of degrees of freedom. For example, the sample stage 134 may include, but is not limited to, one or more linear actuators (e.g., 3-axis linear actuators), rotational actuators, or tip/tilt actuators.

The collection sub-system 110 may include one or more optical components suitable for capturing light from the sample 104 (e.g., collected light 122) as well as manipulating this collected light 122. For example, the collection sub-system 110 may include one or more collection lenses 136 to relay pupil and/or field planes, one or more polarizers to adjust the polarization of the collected light 122, one or more beam blocks, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

The detector 114 may be located at any selected location within the collection sub-system 110. In embodiments, as depicted in FIG. 1B, the detector 114 is located at a pupil plane 138 (e.g., a diffraction plane) to generate a pupil image. For example, the pupil plane 138 may correspond to a back focal plane of the objective lens 112 or a conjugate plane thereof. In this regard, a pupil image generated by the detector 114 may correspond to an angular distribution of light from the sample 104 captured by the detector 114. For instance, diffraction orders associated with diffraction of the one or more illumination beams 106 from the sample 104 (e.g., an overlay target 102 on the sample 104) may be imaged or otherwise observed in the pupil plane 138. In a general sense, the detector 114 may capture any combination of reflected (or transmitted), scattered, or diffracted light from the sample 104.

The optical sub-system 108 may generally include any number or type of detectors 114 suitable for capturing light from the sample 104 indicative of overlay. In embodiments, the detector 114 includes one or more detectors 114 suitable for characterizing a static sample. In this regard, the optical sub-system 108 may operate in a static mode in which the sample 104 is static during a measurement. For example, a detector 114 may include a two-dimensional pixel array such as, but not limited to, a charge-coupled device (CCD) or a complementary metal oxide semiconductor (CMOS) device. In this regard, the detector 114 may generate a two-dimensional image (e.g., a field-plane image or a pupil-plan image) in a single measurement.

In embodiments, the detector 114 includes one or more detectors 114 suitable for characterizing a moving sample 104 (e.g., a scanned sample). In this regard, the optical sub-system 108 may operate in a scanning mode in which the sample 104 is scanned with respect to a measurement field during a measurement. For example, the detector 114 may include a 2D pixel array with a capture time and/or a refresh rate sufficient to capture one or more images during a scan within selected image tolerances (e.g., image blur, contrast, sharpness, or the like). By way of another example, the detector 114 may include a line-scan detector to continuously generate an image one line of pixels at a time. By way of another example, the detector 114 may include a time-delay integration (TDI) detector. A TDI detector may generate a continuous image of the sample 104 when the motion of the sample 104 is synchronized to charge-transfer clock signals in the TDI detector.

In embodiments, the optical sub-system 108 includes a scanning sub-system (not shown) to scan the sample 104 with respect to the optical sub-system 108 during a metrology measurement. For example, the sample stage 134 may position and orient the sample 104 within a focal volume of the objective lens 112. As another example, the scanning sub-system includes one or more beam-scanning optics (e.g., rotatable mirrors, galvanometers, or the like) to scan the one or more illumination beams 106 with respect to the sample 104.

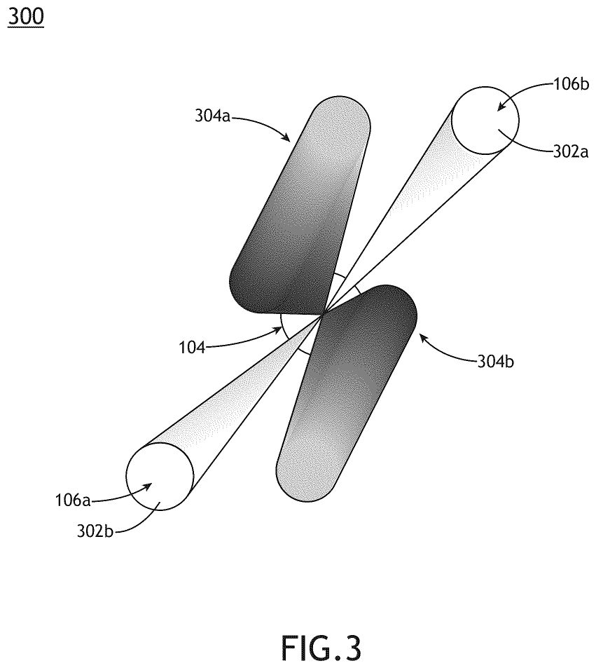

Referring now to FIGS. 3-8, various non-limiting configurations for the generation and pupil images from a grating-over-grating structure 202 with one or more broadband OTL illumination beams 106 is described, in accordance with one or more embodiments of the present disclosure.

As previously discussed herein, the first periodic feature 204 and the second periodic feature 208 of a grating-over-grating structure 202 may act as diffraction gratings, where diffraction lobes (e.g., first-order diffraction lobes, or the like) of a broadband illumination beam 106 may be spectrally dispersed.

FIG. 3 is a three-dimensional perspective top view 300 of a sample 104 depicting diffraction of two broadband illumination beams 106 in a rotated dipole configuration, in accordance with one or more embodiments of the present disclosure. In particular, FIG. 3 depicts a first illumination beam 106a and a second illumination beam 106b incident on the sample 104, where the first illumination beam 106a and the second illumination beam 106b have opposing azimuth incidence angles and common polar incidence angles (e.g., common altitude incidence angles). In this configuration, zero-order diffraction is not spectrally-dispersed, but higher-order diffraction is spectrally-dispersed. Further, zero-order diffraction 302a of the first illumination beam 106a overlaps with the second illumination beam 106b, while zero-order diffraction 302b of the second illumination beam 106b overlaps with the first illumination beam 106a. FIG. 3 further depicts spectrally-dispersed first-order diffraction 304a from the first illumination beam 106a and spectrally-dispersed first-order diffraction 304b from the second illumination beam 106b. In particular, the grating-over-grating structure 202 diffracts each wavelength in a broadband illumination beam 106 to a different angle based on the grating equation, where the angle is related to wavelength 1 divided by the pitch P.

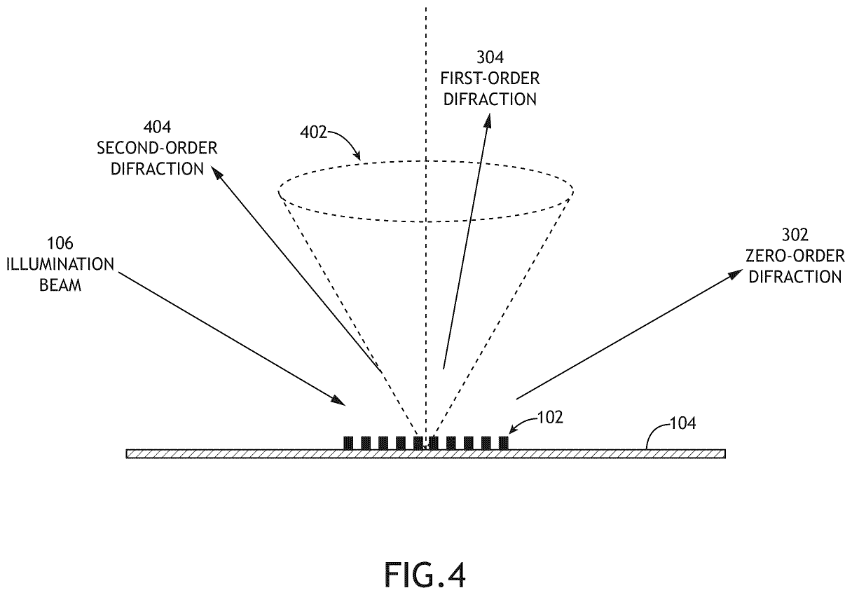

FIGS. 4-8 depict the implementation of overlay measurements using a first-order SCOL technique as a non-limiting example. As described previously herein, this technique may utilize an overlay target 102 including two cells per measurement direction 212, where each cell includes a grating-over-grating structure 202 with a known intended offset f. For example, the overlay target 102 may include a first cell with a first grating-over-grating structure 202 having an intended offset +f₀ along a first measurement direction 212, a second cell with a second grating-over-grating structure 202 having an intended offset −f₀ along the first measurement direction 212, a third cell with a third grating-over-grating structure 202 having an intended offset +f₀ along a second measurement direction 212 (e.g., orthogonal to the first measurement direction 212), and a fourth cell with a fourth grating-over-grating structure 202 having an intended offset −f₀ along the second measurement direction 212.

In this configuration, an overlay metrology system 100 may generate at least one pupil image of each cell, where each pupil image is generated using one or more broadband illumination beams 106 in an OTL configuration. In a general sense, any number of broadband illumination beams 106 may be used to generate each pupil image.

In some embodiments, one or more pupil images are generated (e.g., in accordance with a metrology recipe) for each cell based on two broadband illumination beams 106 with opposing azimuth incidence angles and common altitude incidence angles, where the two azimuthally-opposed broadband illumination beams 106 are mutually coherent. Notably, a quadrupole configuration of illumination beams 106, where only two of the illumination beams 106 contribute to any particular pupil image depending on the orientations of the illumination beams 106 relative to the measurement direction 212 in a particular cell. Further, the metrology recipe may provide that only a single spectrally-dispersed first-order diffraction lobe from each opposing illumination beam 106 is captured by the objective lens 112.

As an illustration, FIG. 4 is a simplified schematic depicting the collection of first-order diffraction 304 from an illumination beam 106 in an OTL configuration, in accordance with one or more embodiments of the present disclosure. In FIG. 4, an illumination beam 106 is directed to an overlay target 102 with a grating-over-grating structure 202 outside a numerical aperture 402 of an objective lens 112 (not shown in the figure). In this configuration, only first-order diffraction 304 lies within the numerical aperture 402 of an objective lens 112 and is thus collected, whereas zero-order diffraction 302 as well second-order diffraction 404 are outside the numerical aperture 402 of an objective lens 112 and are thus not collected. Notably, FIG. 4 depicts only a single illumination beam 106 and associated diffraction for clarity. However, illumination with a pair of azimuthally-opposed illumination beams 106 may result in the collection of a single lobe of first-order diffraction 304 from each of the azimuthally-opposed illumination beams 106.

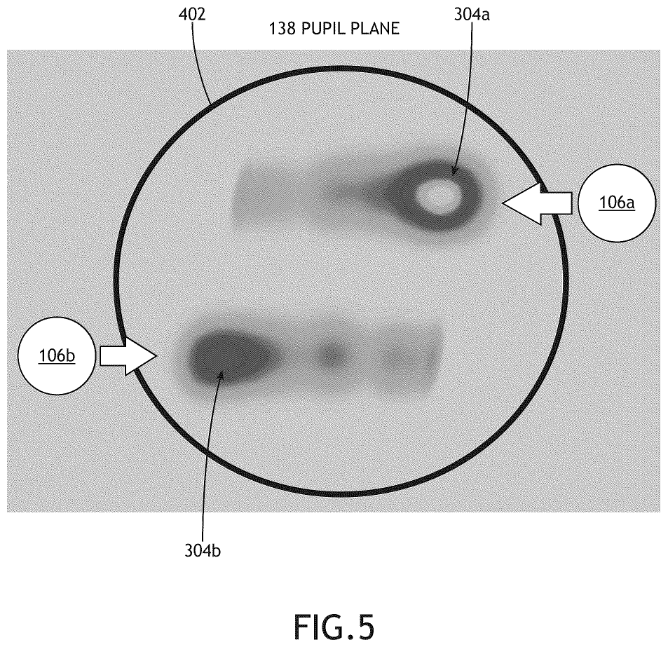

FIG. 5 depicts a top view of a pupil plane 138 depicting simultaneous collection of spectrally-dispersed first-order diffraction from two azimuthally-opposed illumination beams 106 in a rotated dipole configuration, in accordance with one or more embodiments of the present disclosure. In FIG. 5, a first illumination beam 106a and a second illumination beam 106b are depicted outside the numerical aperture 402 of an objective lens 112, which provides OTL illumination. FIG. 5 further depicts a single lobe of spectrally-dispersed first-order diffraction 304a associated with the first illumination beam 106a as well as a single lobe of spectrally-dispersed first-order diffraction 304b associated with the second illumination beam 106b. In particular, the first-order diffraction 304a,b is spectrally dispersed along the horizontal direction of the figure, which corresponds to the measurement direction 212. Notably, the rotated dipole configuration of the illumination beams 106a,b provides that the associated spectrally-dispersed lobes of first-order diffraction 304a,b do not overlap in the pupil plane 138.

In embodiments, an overlay measurement of the overlay target 102 along a particular measurement direction 212 may be generated based on pupil images of cells with grating-over-grating structures 202 having different intentional offsets f.

For example, differential signals (D_{±}) may be calculated in a case with two cells with opposite intentional shifts (±f₀) based on Equation 1 below:

$${D}_{\pm } = {S}_{+ 1} ( \pm {f}_{0} ) - {S}_{- 1} ( \pm {f}_{0} ) . \qquad ( 1 )$$

where S₊₁ is a first diffraction order signal from a first illumination beam 106 and S₋₁ is a first diffraction order signal from a second illumination beam 106. For example, differential signal D₊ may be generated from a first pupil image of a cell with an intentional offset of +f₀, whereas differential signal D₋ may be generated from a second pupil image of a cell with an intentional offset of −f₀.

The per-pixel overlay (∈) may then be obtained from Equation 2:

$$∈ \approx {f}_{0} \frac{{D}_{+} + {D}_{-}}{{D}_{+} - {D}_{-}} . \qquad ( 2 )$$

It is contemplated herein that the per-pixel overlay (∈) may be calculated for many different portions of the pupil. Notably, the use of broadband illumination beams 106 allows for simultaneous per-pixel overlay (∈) calculations for multiple wavelengths since the different wavelengths are dispersed across the pupil images. Put another way, a full pupil landscape may be captured in a single grap.

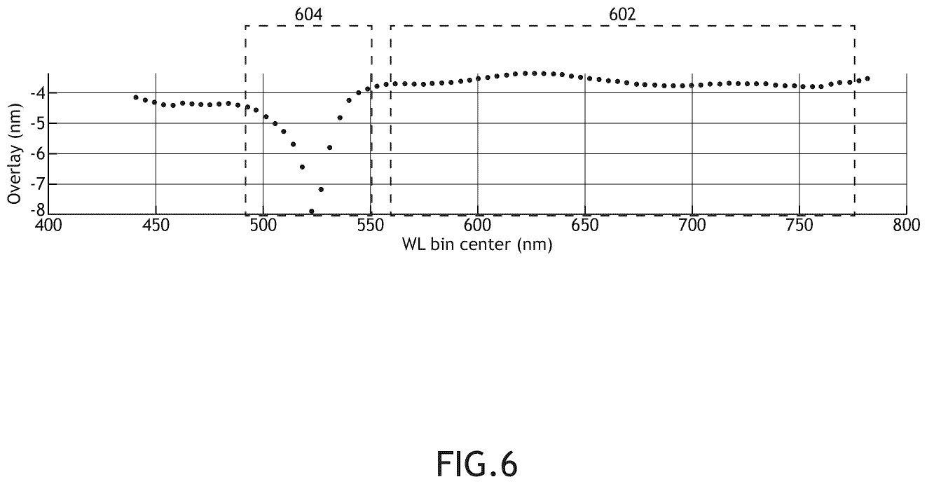

FIG. 6 is a plot of a full pupil landscape generated by pupil images of the type depicted in FIG. 5, in accordance with one or more embodiments of the present disclosure. In particular, FIG. 6 is a plot of per-pixel overlay (∈) calculated as a function of wavelength, where the different wavelengths are spatially distributed in pupil images as shown in FIG. 5. Notably, FIG. 6 demonstrates that a pupil landscape may include one or more regions of stability 602 (e.g., green zones), where the overlay measurement is relatively stable against deviations of the wavelength or process deviations more generally. For instance, the regions of stability 602 may be viewed as plateaus in the landscape plot of FIG. 6. Further, the pupil landscape may include resonance regions 604, where the overlay measurement varies substantially with small deviations of the wavelength or process deviations more generally.

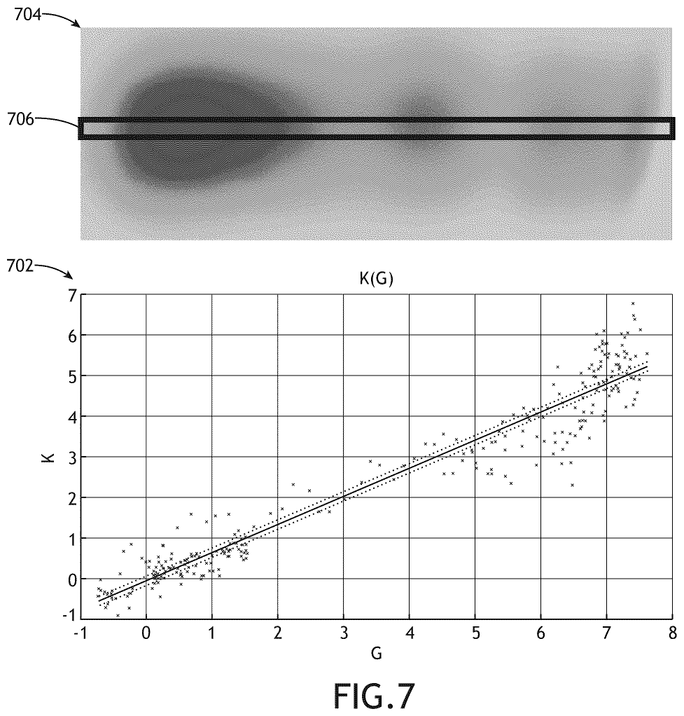

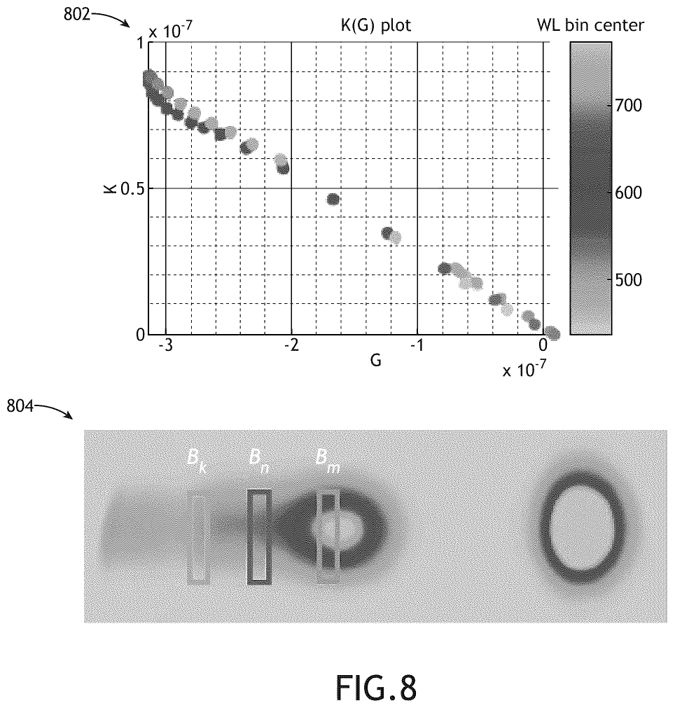

Referring now to FIGS. 7-8, multi-wavelength algorithms for overlay measurements based on broadband illumination beams 106 are described in greater detail.

More generally, overlay (OVL) may be described by Equations 3-4 below:

$$K \approx \frac{∈}{{f}_{0}} G \qquad ( 3 )$$

$$OVL = {f}_{0} \frac{K}{G} \qquad ( 4 )$$

where G=D₁−D₂, and K=D₁+D₂.

Based on this formulation, many different K and G datapoints may be generated from pupil images and an overlay measurement (OVL) may be generated based on a slope of these K and G datapoints.

The broadband pupil data may enable recipe-free, ultra-robust measurements using a variety of techniques. For example, multiple wavelengths within an identified region of stability 602 (e.g., green zone) may be used to obtain an overlay measurement. More generally, pupil images generated using broadband illumination beams 106 may be binned in various ways to generate an overlay measurement.

FIG. 7 depicts a plot 702 of K and G datapoints generated based on bins generated parallel to a wavelength dispersion direction in pupil images (e.g., parallel to the measurement direction 212), in accordance with one or more embodiments of the present disclosure. For example, inset 704 depicts a portion of one pupil image showing a binning technique defined by box 706 used to generate the K and G datapoints in the plot 702. In this configuration, the overlay (OVL) may be determined as a slope of the K and G datapoints based on Equations (3) and (4) above.

FIG. 8 depicts a plot 802 of K and G datapoints generated based on bins generated perpendicular to a wavelength dispersion direction in pupil images (e.g., perpendicular to the measurement direction 212), in accordance with one or more embodiments of the present disclosure. For example, inset 804 depicts three different portions of one pupil image showing a binning technique used to generate the K and G datapoints in the plot 802. In particular, the inset 804 shows three binning windows labeled Bk, Bn, and Bm. Again, the overlay (OVL) may be determined as a slope of the K and G datapoints based on Equations (3) and (4) above.

It is noted that FIGS. 7 and 8 and the associated descriptions are provided solely for illustrative purposes and should not be interpreted as limiting the scope of the present disclosure. In particular, an overlay measurement may be generated based on pupil images of various cells of an overlay target 102 using any suitable technique. Further, the present disclosure is not limited to first-order SCOL techniques.

It is also contemplated herein that the K signals may depend on the actual values of overlay at the location of an overlay target, whereas the G signals may depend on physical properties of the overlay target design and relate to a sensitivity of the target to overlay variations. For this reason, this G signal may be referred to as a sensitivity metric. Since the G signal (e.g., the sensitivity metric) does not depend directly on the actual overlay at a particular location of an overlay target, the G signal may be obtained from another source and thus need not be measured at every overlay target. As a result, the number of cells required for an overlay target to obtain an overlay measurement may be reduced when the G signal is obtained from another source, which may beneficially decrease measurement times and increase measurement throughput across the sample. Continuing the illustration of first-order SCOL techniques, a single-cell overlay target may be used when the G signal is obtained from another source.

It is further contemplated herein that the sensitivity metrics (e.g., the G signals) relate to physical attributes of the overlay target design. As a result, variations of these sensitivity metrics across a sample may relate to variations of the physical attributes of the overlay targets across the wafer, which typically occurs over length scales much greater than overlay variations. For example, overlay variations may vary significantly within each lithographic exposure field, whereas the physical attributes of the overlay targets (and thus the sensitivity metrics) may vary relatively slowly across several fields. Sensitivity metrics measured at one location may thus be relevant to multiple targets within a field or potentially between fields.

As previously discussed herein, the system and method of the present disclosure may provide numerous benefits. For example, the system and method of the present disclosure may provide a more robust method for employing existing overlay measurement techniques. For instance, the spectrum of first-order diffraction lobes 302a,b may be spatially dispersed in the pupil plane 138 such that overlay measurements may be generated based on single-wavelength overlay measurements may be generated.

It is further contemplated herein that the OTL illumination configuration disclosed herein provides numerous advantages over a TTL illumination configuration such as that described in U.S. patent application Ser. No. 18/370,136 filed on Sep. 19, 2023, titled SINGLE GRAB PUPIL LANDSCAPE VIA BROADBAND ILLUMINATION, which is incorporated herein by reference. For example, the OTL configuration depicted in FIG. 5 may allow for smaller values of the pitch P of the grating-over-grating structure 202, which may allow for a closer match between this pitch and pitches of device features on the sample 104 as well as a reduction of target size. As another example, the OTL configuration depicted in FIG. 5 beneficially does not collect zero-order diffraction 302a,b (e.g., as shown in FIG. 3), which allow for increased physical spreading of the spectrally-dispersed first-order diffraction 304a,b in a pupil image and may further avoid blooming in the detector 114 associated with the relatively strong zero-order diffraction 302a,b.

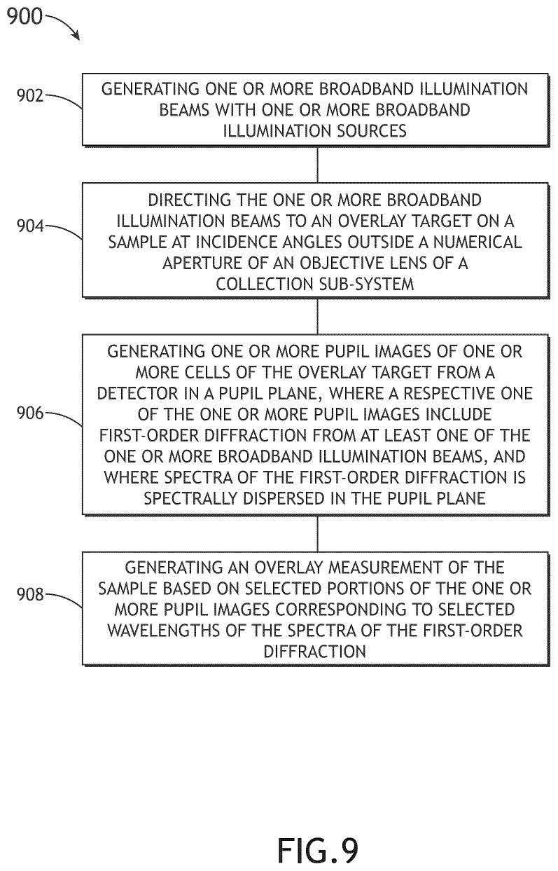

FIG. 9 is a flowchart depicting a method 900 for taking overlay measurements using a broadband illumination source, in accordance with one or more embodiments of the present disclosure. Applicant notes that the embodiments and enabling technologies described previously herein in the context of the overlay metrology system 100 should be interpreted to extend to the method 900. For example, processors of the controller may be configured to execute program instructions causing the processors to implement various steps of the method 900 either directly or indirectly. However, the method 900 is not limited to the architecture of the overlay metrology system 100.

In embodiments, the method 900 includes a step 902 of generating one or more broadband illumination beams with one or more broadband illumination sources. In embodiments, the method 900 includes a step 904 of directing the one or more broadband illumination beams to an overlay target on a sample at incidence angles outside a numerical aperture of an objective lens of a collection sub-system (e.g., in an OTL configuration) when implementing a metrology recipe, where the overlay target in accordance with the metrology recipe includes one or more cells having periodic features formed grating-over-grating structures. In embodiments, the method 900 includes a step 906 of generating one or more pupil images of the one or more cells from a detector in a pupil plane of the collection sub-system, where a respective one of the one or more pupil images include first-order diffraction from at least one of the one or more broadband illumination beams, and where spectra of the first-order diffraction is spectrally dispersed in the pupil plane. For example, the one or more pupil images may be generated by the detector 114 and received by the controller 124. In embodiments, the method 900 includes a step 908 of generating an overlay measurement of the sample based on selected portions of the one or more pupil images corresponding to selected wavelengths of the spectra of the first-order diffraction.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An overlay metrology system comprising:
a collection sub-system including an objective lens and detector located at a pupil plane;
an illumination sub-system comprising:
one or more broadband illumination sources configured to generate one or more broadband illumination beams; and
one or more illumination optics configured to direct the one or more broadband illumination beams to an overlay target on a sample at incidence angles outside a numerical aperture of the objective lens, wherein the overlay target in accordance with a metrology recipe includes one or more cells having periodic features formed grating-over-grating structures; and
a controller communicatively coupled to the detector, the controller including one or more processors configured to execute program instructions causing the one or more processors to implement the metrology recipe by:
receiving one or more pupil images of the one or more cells from the detector in the pupil plane, wherein a respective one of the one or more pupil images include first-order diffraction from at least one of the one or more broadband illumination beams, wherein spectra of the first-order diffraction is spectrally dispersed in the pupil plane; and
generating an overlay measurement of the sample based on selected portions of the one or more pupil images corresponding to selected wavelengths of the spectra of the first-order diffraction.

2. The overlay metrology system of claim 1, wherein the one or more pupil images include a first pupil image of a first cell of the overlay target and a second pupil image of a second cell of the overlay target.

3. The overlay metrology system of claim 1, wherein a respective one of the one or more pupil images is formed based on two mutually coherent broadband illumination beams of the one or more broadband illumination beams.

4. The overlay metrology system of claim 3, wherein the two mutually coherent broadband illumination beams are oriented at opposing azimuth incidence angles.

5. The overlay metrology system of claim 3, wherein the respective one of the one or more pupil images is formed based on a single lobe of the first-order diffraction from each of the two mutually coherent broadband illumination beams.

6. The overlay metrology system of claim 1, wherein the overlay measurement is based on per-pixel overlay measurements associated with a plurality of wavelengths in the first-order diffraction.

7. The overlay metrology system of claim 1, wherein generating the overlay measurement of the sample based on the selected portions of the one or more pupil images corresponding to the selected wavelengths of the spectra of the first-order diffraction further comprises:
identifying one or more regions of the one or more pupil images associated with the selected wavelengths, wherein the one or more regions correspond to one or more regions of stability providing insensitivity of the overlay measurement to overlay process variations within a selected tolerance.

8. The overlay metrology system of claim 1, wherein the one or more broadband illumination sources comprise a rotated quadrupole illumination source providing oblique illumination beams along two orthogonal directions in the pupil plane.

9. The overlay metrology system of claim 1, wherein the one or more processors are further configured to:
store the overlay measurement in memory when implementing the metrology recipe; and
adjust one or more process parameters based on the overlay measurement.

10. The overlay metrology system of claim 1, wherein the detector includes a charge-coupled device or a complementary metal oxide semiconductor device.

11. The overlay metrology system of claim 1, wherein the sample includes a substrate.

12. The overlay metrology system of claim 11, wherein the sample includes a wafer.

13. An overlay metrology system comprising:
a controller communicatively coupled to a detector in a pupil plane of a collection sub-system, the controller including one or more processors configured to execute program instructions causing the one or more processors to implement a metrology recipe by:
receiving one or more pupil images of one or more cells of an overlay target on a sample from the detector, wherein the one or more pupil images are generated based on illumination of the overlay target with one or more broadband illumination beams at incidence angles outside a numerical aperture of an objective lens of the collection sub-system, wherein a respective one of the one or more pupil images include first-order diffraction from at least one of the one or more broadband illumination beams, wherein spectra of the first-order diffraction is spectrally dispersed in the pupil plane; and
generating an overlay measurement of the sample based on selected portions of the one or more pupil images corresponding to selected wavelengths of the spectra of the first-order diffraction.

14. The overlay metrology system of claim 13, wherein the one or more pupil images include a first pupil image of a first cell of the overlay target and a second pupil image of a second cell of the overlay target.

15. The overlay metrology system of claim 13, wherein a respective one of the one or more pupil images is formed based on two mutually coherent broadband illumination beams of the one or more broadband illumination beams.

16. The overlay metrology system of claim 15, wherein the two mutually coherent broadband illumination beams are oriented at opposing azimuth incidence angles.

17. The overlay metrology system of claim 15, wherein the respective one of the one or more pupil images is formed based on a single lobe of the first-order diffraction from each of the two mutually coherent broadband illumination beams.

18. The overlay metrology system of claim 13, wherein the overlay measurement is based on per-pixel overlay measurements associated with a plurality of wavelengths in the first-order diffraction.

19. The overlay metrology system of claim 13, wherein generating the overlay measurement of the sample based on the selected portions of the one or more pupil images corresponding to the selected wavelengths of the spectra of the first-order diffraction further comprises:
identifying one or more regions of the one or more pupil images associated with the selected wavelengths, wherein the one or more regions correspond to one or more regions of stability providing insensitivity of the overlay measurement to overlay process variations within a selected tolerance.

20. The overlay metrology system of claim 13, wherein the one or more broadband illumination beams are in a rotated quadrupole distribution.

21. The overlay metrology system of claim 13, wherein the detector includes a charge-coupled device or a complementary metal oxide semiconductor detector.

22. The overlay metrology system of claim 13, wherein the one or more processors are further configured to:
store the overlay measurement in memory when implementing the metrology recipe; and
adjust one or more process parameters based on the overlay measurement.

23. The overlay metrology system of claim 13, wherein the sample includes a substrate.

24. The overlay metrology system of claim 23, wherein the sample includes a wafer.

25. A method comprising:
generating one or more broadband illumination beams with one or more broadband illumination sources;
directing the one or more broadband illumination beams to an overlay target on a sample at incidence angles outside a numerical aperture of an objective lens of a collection sub-system when implementing a metrology recipe, wherein the overlay target in accordance with the metrology recipe includes one or more cells having periodic features formed grating-over-grating structures;
generating one or more pupil images of the one or more cells from a detector in a pupil plane of the collection sub-system, wherein a respective one of the one or more pupil images include first-order diffraction from at least one of the one or more broadband illumination beams, wherein spectra of the first-order diffraction is spectrally dispersed in the pupil plane; and
generating an overlay measurement of the sample based on selected portions of the one or more pupil images corresponding to selected wavelengths of the spectra of the first-order diffraction.
